(19) United States
(12) Patent Application Publication
(10) Pub. No.: US 2006/0088875 A1
(43) Pub. Date: Apr. 27, 2006

(54) Means for electrical contacting or isolation of organic or inorganic semiconductors and a method for its fabrication

(76) Inventors: Thomas Jackson, State College, PA (US); Jianna Wang, Waltham, MA (US)

Correspondence Address: BIRCH STEWART KOLASCH & BIRCH, PO BOX 747, FALLS CHURCH, VA, 22040-0747, US

(21) Appl. No.: 11/261,494

(22) Filed: Oct. 31, 2005

Related U.S. Application Data
(63) Continuation of application No. 09/763,948, filed on Jun. 8, 2001, now abandoned.

(30) Foreign Application Priority Data
Jun. 30, 1999 (NO) 19993266

(51) Int. Cl. C12Q 1/68; C12M 1/34; B05D 3/00

(52) U.S. Cl. 435/6; 435/287.2; 427/2.11

(57) ABSTRACT

In a means for electrical contacting or isolation of organic or inorganic semiconductors in electronic and optoelectronic devices, particularly thin-film devices, the means comprises a substrate (1) in the form of a contact material (1a) or an isolating material (4). A charge transfer material (2) is provided patterned or unpatterned on or at the surface of the substrate and includes charge transfer components in the form of donors and/or acceptors. The charge transfer material forms a self-assembling layer (3) on one or more atomic and/or molecular layers. The charge transfer material (2) has a direct or indirect bond to the surface of the substrate (1) and further forms a charge transfer complex with a thereabove adjacently provided organic or inorganic semiconductor (6). The charge transfer material (2) then forms a donor or acceptor material in the charge transfer complex depending upon respectively whether the semiconductor (6) itself is an acceptor or donor material.

This application is a Continuation of co-pending application Ser. No. 09/763,948 filed on Jun. 8, 2001, which is the national stage application of PCT/NO00/00228, filed on Jun. 30, 2000 and for which priority is claimed under 35 U.S.C. § 120; and this application claims priority of Application No. 19993266 filed in Norway on Jun. 30, 1999 under 35 U.S.C. § 119; the entire contents of all are hereby incorporated by reference.

The invention concerns a means for electrical contacting or isolation of organic or inorganic semiconductors in electronic and optoelectronic devices, particularly thin-film devices, wherein the means comprises a substrate either in the form of contact material consisting of an organic or inorganic electrical conductor, or in the form of an isolating material consisting of an organic or inorganic dielectric.

The invention also concerns a method for fabricating a means for electrical contacting or isolation of organic or inorganic semiconductors in electronic and optoelectronic devices, particularly thin-film devices, wherein the means comprises a substrate either in the form of contact material consisting of an organic or inorganic electrical conductor, or in the form of an isolating material consisting of an organic or inorganic dielectric.

Electrical contacts in electronic and optoelectronic devices made with inorganic semiconductor material may frequently present problems. The devices, including thin-film transistors and light-emitting devices, often make use of the isolating properties of the inorganic semiconductor materials, for instance in order to provide low current levels in thin-film transistors in the off-state. However, high resistivity in the semiconductor material can make the current injection at the contacts problematic. Generally metals or other conductors with a given work function are used in order to improve the contact properties by reducing the injection barrier, but this has been successful only to a limited degree. Doping of the organic semiconductor medium or local surface doping, occasionally in combination, has also been attempted. It has been shown that doping of oligothiophenes with iodine (I₂), iron (III) or chloride (e.g. FeCl₃) increases the conductivity of oligothiophene with up to 0,1 S cm⁻¹ (see for instance S. Hotta & K. Waragai, Journal of Material Chemistry, 1:835 (1991) and D. Fichou, G. Horowitz, X. B. Xu & F. Garnier, Synthetic Metals 41:463 (1991)), and that a doping of this kind can improve the contacts (Y. Y. Lin, D. J. Gundlach & T. N. Jackson, Materials Research Society, Symposium Proceedings, pp. 413-418 (1996)). However, it is difficult to achieve selective doping, and the high mobility of ionic dopants (I₃⁻ or FeCl₄⁻ usually results in poor device stability. Organic molecular dopants such as tetracyanoquinodimethane (TCNQ) have also been used (F. Garnier, F. Kouki, R. Hajlaoi & G. Horowits, Materials Research Society Bulletin, June 1997, pp. 52-56). A thin layer, e.g. about 4 nm thick, of TCNQ was deposited in vacuum between an organic semiconductor layer and source and drain electrodes of gold in a thin-film transistor. However, organic molecular charge transfer materials, which can be deposited by evaporation or other simple methods, have a poor film-forming property and this limits their application. Nor is it clear that a doping of this kind will be significantly more stable than inorganic doping. In addition it is necessary with lithography or other patterning procedures in order to align the charge transfer layers with source/drain contacts of organic thin-film transistors.

The primary object of the present invention is thus to overcome the problems with prior art and provide improved contacts for contacting of organic as well as inorganic semiconductors in electronic and optoelectronic devices, particularly thin-film devices. Particularly it is the object to provide an improved contact without additional patterning of the device layers being necessary, while instabilities due to diffusion and field effects are avoided. Further it is an object of the present invention to provide an isolation of organic or inorganic semiconductors in electronic and optoelectronic devices, particularly a selective isolation in order to reduce and eliminate leakage current in an electronic semiconductor layer outside the active area in the device or in order to reduce the effective channel length in organic or inorganic field effect transistors realized in thin-film technology.

The above-mentioned objects are achieved according to the invention with a means which is characterized in that it further comprises a charge transfer material provided patterned or unpatterned on or at a surface of the substrate, the charge transfer material including charge transfer components in the form of donors and/or acceptors, that the charge transfer material forms a self-assembling layer of one or more atomic and/or molecular layers, that the charge transfer material has a direct or indirect bond to the surface of the substrate, and that the charge transfer material forms a charge transfer complex with a thereabove adjacently provided organic or inorganic semiconductor, the charge transfer material forming a donor or acceptor material in the charge transfer complex depending upon respectively whether the semiconductor itself is an acceptor or donor material.

Preferably the bond to the surface of the substrate is a chemical or electrostatic bond or a combination thereof.

In a first embodiment of the means according to the invention, the charge transfer material is an organic compound and may preferably comprise a functional group which forms the bond to the surface of the substrate. Preferably the functional group can be material selective and form the bond to a specific substrate material.

In another embodiment of the means according to the invention, wherein the charge transfer material is provided at the surface of the substrate, the means comprises a connection layer without charge transfer components provided between the surface of the substrate and the charge transfer material, the connection layer forming a bond to the surface of the substrate and a bond to the charge transfer material.

Preferably is then the bond in each case a chemical or electrostatic bond or a combination thereof. The connection layer can preferably be formed of an organic bonding agent and particularly the organic bonding agent can be formed of DNA molecules, such that the one half strand of a DNA molecule is bonded to the surface of the substrate and the complementary second half strand of the DNA molecule is bonded to the charge transfer material.

In an advantageous variant embodiment of the means according to the invention the charge transfer material is an atomic or molecular inorganic compound. Where the charge transfer inorganic compound is provided on the surface of the substrate, the inorganic compound is then preferably formed of a material which reacts chemically with the substrate and between the substrate and the inorganic compound forms a connection layer consisting of a chemical compound of the substrate material and the inorganic compound. If the charge transfer inorganic compound is provided at the surface of the substrate, the means then preferably comprises a connection layer between the substrate and the inorganic compound, the connection layer consisting of a chemical compound of the substrate material or a material with similar chemical properties, and the charge transfer inorganic compound.

A method for fabricating the means according to the invention is characterized by providing a charge transfer material as a patterned or unpatterned self-assembling layer of one or more atomic and/or molecular layers on or at a surface of the substrate, the charge transfer material including charge transfer components in the form of donors and/or acceptors, forming a direct or indirect bond between the charge transfer material and the surface of the substrate, and forming a charge transfer complex of the charge transfer material together with a thereabove adjacently provided organic or inorganic semiconductor, the charge transfer material forming a donor or acceptor material in the charge transfer complex depending upon respectively whether the semiconductor itself is an acceptor or donor material.

Preferably the bond is formed in the method according to the invention as a chemical or electrostatic bond or a combination thereof.

In a first embodiment of the method according to the invention the charge transfer material advantageously is selected as an organic compound, preferably with a functional group which forms the bond to the surface of the substrate. Preferably the functional group can be a material-selective group such that the bond is formed to a specific substrate material.

In a second embodiment of the method according to the invention, wherein the charge transfer material is provided at the surface of the substrate, a connection layer without a charge transfer component is provided between the surface of the substrate and the charge transfer material, the connection layer being formed with a bond to the surface of the substrate and with a bond to the charge transfer material. Preferably the bond in each case is formed as a chemical or electrostatic bond or a combination thereof.

The connection layer can advantageously be formed of an organic bonding agent and particularly the organic bonding agent can be formed of DNA molecules, such that the one half strand of DNA molecule is bonded to the surface of the substrate and the complementary second half strand of the DNA molecule is bonded to the charge transfer material.

In an advantageous variant embodiment of the method according to the invention, the charge transfer material is advantageously selected as an atomic or molecular inorganic compound. Where the charge transfer inorganic compound is provided on the surface of the substrate, the inorganic compound is then preferably formed of an material which reacts chemically with the substrate, such that between the substrate and the inorganic compound a connection layer consisting of a chemical compound of the substrate material and the inorganic compound is formed. Where the charge transfer inorganic compound is provided at the surface of the substrate, a connection layer consisting of a compound of the substrate material or a material with similar chemical properties and the inorganic compound is preferably provided between the substrate and the inorganic compound.

The present invention shall now be explained in more detail with reference to exemplary embodiments and in connection with the appended drawings, wherein

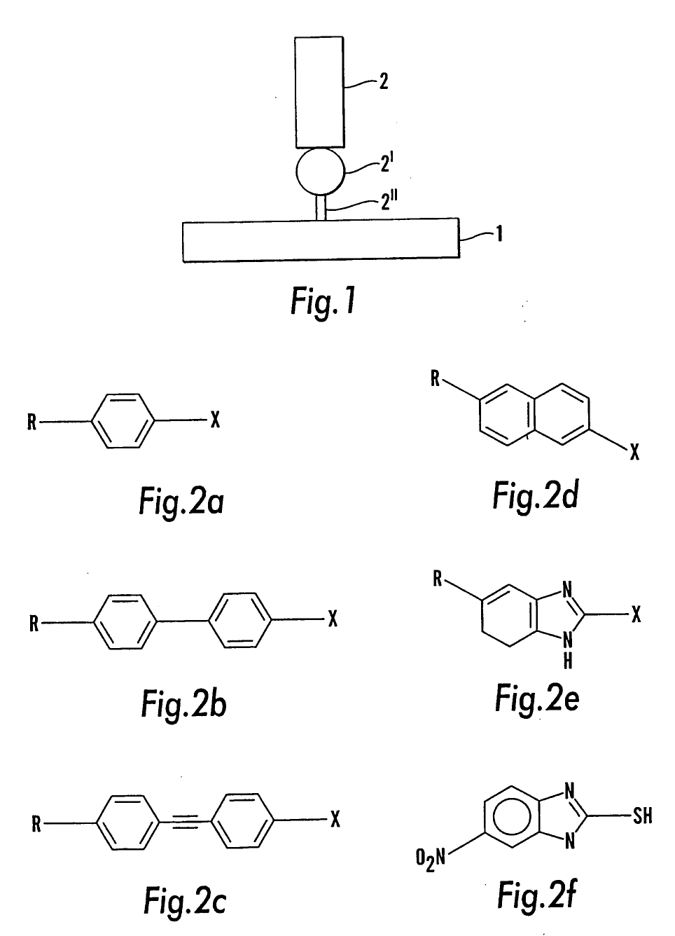

FIG. 1 shows schematically a self-assembling charge transfer molecule on a substrate,

FIG. 2a-e the structure of various organic charge transfer compounds,

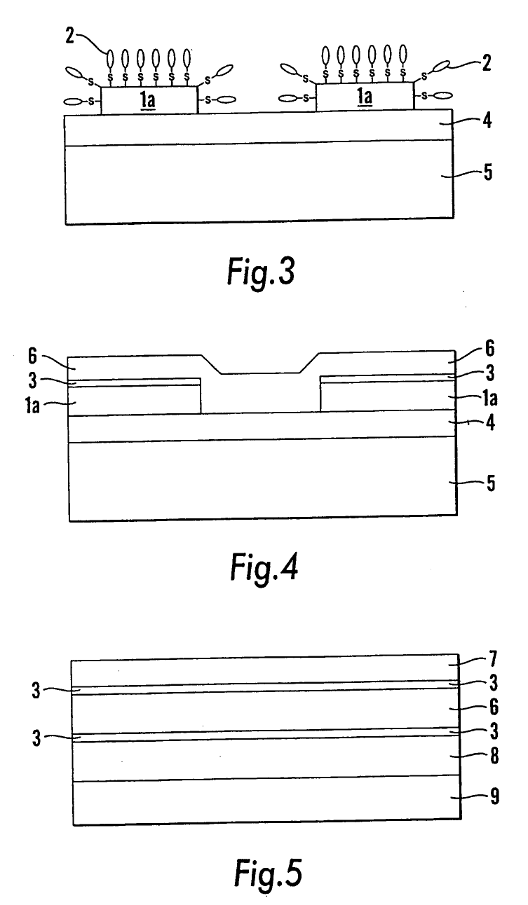

FIG. 3 a schematic section through the means according to the invention used in a thin-film transistor,

FIG. 4 a schematic section through a thin-film transistor with the means according to the invention,

FIG. 5 a schematic section through an organic light-emitting diode in thin-film technology, wherein the means according to the invention is used,

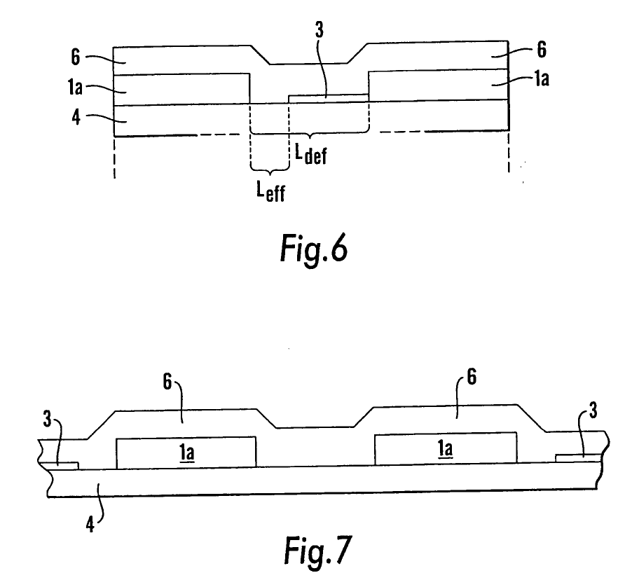

FIG. 6 a schematic section through a portion of a thin-film transistor, wherein the means according to the invention is used,

FIG. 7 a schematic section through a portion of a thin-film transistor, wherein the means according to the invention is used for reducing current leakage, and

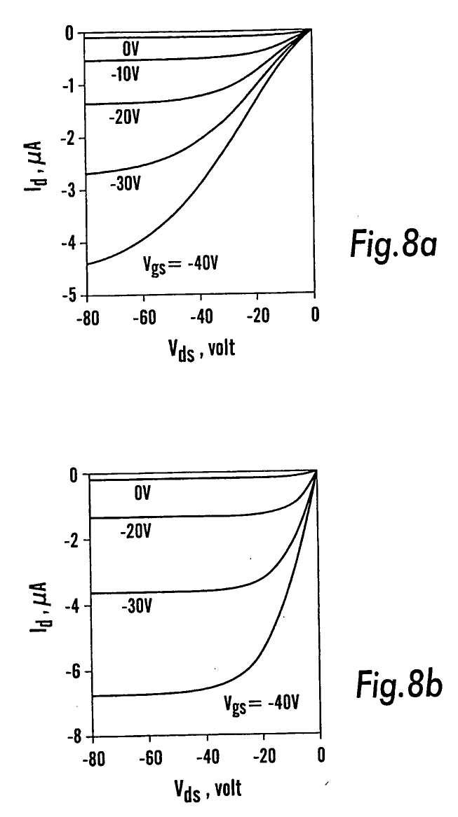

FIG. 8a the current-voltage characteristics of an organic thin-film transistor according to prior art, and

FIG. 8b the current-voltage characteristics of an organic thin-film transistor with the means according to the invention.

First the background of the invention shall briefly be explained. A number of aromatic and other organic molecules may form donor complexes with different compounds. Molecules which are capable of giving up electrons are electron donors. For instance, aromatic hydrocarbons, including alkenes and alkyls, which have π orbitals, are donor molecules in many systems. Molecules which are capable of accepting electrons, are electron acceptors. Aromatic nitro compounds and quinones are π acceptors and halogen molecules with vacant σ antibonding orbitals act as σ acceptors in many systems. For instance can aromatic hydrocarbons such as tetracene and pentacene act as electron donors towards benzoquinones or trinitrobenzene. The effect of introducing a charge donor or charge acceptor in an organic semiconductor corresponds to introducing charge-donating or charge-accepting impurities in an organic semiconductor (K. Tamaru & M. Kchikawa, “Catalysis By Electron Donor-Acceptor Complexes”, Halsted Press, New York (1975)). It shall be remarked that charge transfer often depends on the molecular environment and a single molecule species can sometimes act as a donor or an acceptor depending on the organic semiconductor being considered. In addition it is to be remarked that donor and acceptor materials in no way are limited to organic compounds. There are known inorganic charge transfer materials, including iodine (I₂), iron (III) or ferrichloride (FeCl₃) such as mentioned in the introduction. These may be used when they are given a suitable bond to for instance a contact material.

The means according to the invention can be used both with substrates which are electrical conducting, for instance contact materials as used in thin-film transistors or also, for specific applications, with substrates of a dielectric material, something which shall be mentioned later.

A suitable charge transfer material whose molecules or for the sake of that atoms, may act as donor or acceptors depending on the circumstances, is used to provide local doping of for instance one or more contact areas in a semiconductor device realized in thin-film technology. The means according to the invention achieves good stability by the charge storage components being attached to the contact material with a bond which for instance may be chemical, electrostatic or another suitable bonding mechanism, possibly combinations of several such bonding mechanisms. Basically this may according to the invention be achieved in two different ways.

In a first method the charge transfer material are used in the form of a compound which for instance forms a chemical bond to the substrate surface. In some cases a charge transfer compound of this kind will form a self-assembling monolayer (SAM). This may can used for minimizing the thickness of layers of charge transfer material, but is not essential in order to form contact areas which are locally doped with charge transfer material. FIG. 1 shows schematically a charge transfer molecule 2 bound to a substrate 1, for instance a metal surface. The functional head group 2′ in the charge transfer molecule 2 then forms a chemical bond 2″ with a surface 1.

FIGS. 2a-f show some examples of charge transfer organic compounds with a functional head group. Here the bonds are respectively F, Cl or NO₂, and X denotes respectively —NC or —SH.

FIG. 2a shows the structure of 4,4′-substituted phenyl, FIG. 2b the structure of 4,4′-substituted biphenyl, FIG. 2c shows the structure of 4,4′-substituted phenylethynyl benzene, FIG. 2d shows the structure of substituted naphthalene, FIG. 2e shows the structure of substituted benzimidazole and finally FIG. 2f shows the structure of 2-mercapto 5-nitrobenzimidazole which is a mercaptan or thiol compound with −SH as functional head group.

For different metal surfaces different functional groups may be used for forming the bond. For instance can mercapto and thiol groups as shown in FIG. 2e and particularly in FIG. 2f, where the mercapto or thiol group are —SH, form strong bonds to surfaces of gold, silver and copper. For platinum may amines (—NH₂) or isonitriles (—NC) be preferred as they can easily form charge transfer bonded layers on a substrate of this kind (A. Ulman, “An Introduction to Ultrathin Organic Films”, Academic Press, Inc. (1991)). It may be mentioned that a large number of materials have been investigated with regard to use as donor or acceptor materials and a large number of compounds which may be used as charge transfer material exists or can be synthesized (see e.g. K. Tamaru and M. Kchikawa, op.cit., and J. E. Katon, “Organic Semiconducting Polymers” Marcel Dekker, Inc., New York (1968)).

The embodiment of the method according to the invention with choosing a charge transfer compound with a functional group which can be bonded directly to a metal surface is simple, but may in some cases limit the choice of charge transfer compounds.

An alternative embodiment of the method according to the invention is hence to first form a connection layer without charge transfer components on the substrate and then to bond the charge transfer components or compounds to this connection layer. This opens for a large number of possibilities for different connection layers and schemes for providing a suitable bond. Typically there may for instance be desirable with a covalent bond to a metal surface and the charge transfer compound may for instance be bonded chemically or electrostatically. In an advantageous variant of the embodiment the one half strand of a DNA molecule is bonded to the substrate. The complementary second half strand of the DNA molecule can afterwards be bonded to the charge transfer molecule and will then form a strong bond to the DNA molecule on the substrate.

The embodiment of the means according to the invention where a charge transfer material 2 is used for improving the current injection of the source or drain electrode in inorganic thin-film transistors is particularly shown in FIG. 3. The charge transfer compound may for instance be 2-mercapto 5-nitrobenzimidazole (MNB), and the organic thin-film transistor may be made with pentacene as the active semiconductive material. The contacts themselves may be made of gold. In FIG. 3 is the MNB molecule 2 shown provided on the source and drain contacts 1a, which in their turn are provided on the gate isolator 4 of the gate electrode 5. The organic semiconductor material is left out in FIG. 3. The functional group S forms the bond between the MNB molecule 2 and the gold surface. In this case S, of course, is a mercapto or thiol group —SH. The MNB molecules 2 form as shown in FIG. 3 a self-assembling monolayer of MNB material, the layer being restricted to the gold electrodes 1a and is only present there, as shown in FIG. 3. The surface is now ready for deposition of the organic semiconducting material, i.e. pentacene, and the circuit can then be completed in the usual manner.

FIG. 4 shows a thin-film transistor where the source and drain contacts 1a are locally doped with an immobilized layer 3 of charge transfer material which forms the charge transfer complex of acceptor or donor materials, i.e. of the charge transfer compound and the active, in this case organic semiconductor 6 which is provided over both the source and drain contacts 1a and the layer of charge transfer material. A gate isolator 4, e.g. of silicon dioxide, provides isolation against the gate electrode 5 which in its turn may be formed by the silicon chip. It shall be understood that the charge transfer material 3 used equally well may be of a species which does not form the layer as a monolayer, but instead as a number of separate atomic and/or molecular layers.

Above the means according to the invention is specifically discussed used in organic thin-film transistors. Improved contacts are of course of great interest for a large number of organic devices and not only restricted to organic thin-film transistors. As examples may be mentioned organic light-emitting diodes, various other organic diodes, organic photovoltaic devices and organic sensors and a large number of other organic electronic and optoelectronic devices. For instance, FIG. 5 shows schematically a section through a light-emitting diode where a layer 3 of a charge transfer material is provided between the cathode 7 and the organic semiconductor material 6. Further an additional layer 3 of charge transfer material is provided between the semiconductor 6 and the anode 8, the anode in its turn being provided on a suitable substrate material 9. The cathode 7 can be made of a transparent material. Possibly it can be the anode 8 and the substrate 9 which are made of a transparent material. The layers 3 of charge transfer material will normally let light through, as they at most will have a thickness of the magnitude one or a few molecules. It is, of course, to be understood that the layer thickness in FIG. 5 as in the remaining figures is not to scale. Typically will the organic semiconducting material, however, form a much thicker layer than the charge transfer material, namely of the magnitude from a few ten nanometers and up to several hundred nanometers.

The means according to the invention is not restricted to comprise an electric contact material, for instance metal, but may also be used for forming charge transfer complexes with a semiconductor material outside the contact areas. This presupposes that the charge transfer material can be bonded to an electrical isolating material, i.e. in practice a dielectric. A bond between a charge transfer material and a dielectric may e.g. be used to displace the threshold voltage either in the positive or negative direction in a field-effect transistor. In a p-channel transistor an acceptor-like charge transfer material will for instance displace the threshold voltage in negative direction, and a donor-like charge transfer material will displace the threshold voltage in a positive direction.

As shown in FIG. 6 the use of a layer 3 of charge transfer material in the channel area can be used to reduce the effective channel length L_{eff}. This corresponds to a reduction of the channel length in for instance field-effect transistors based on single crystal silicon, amorphous silicon or polysilicon. The doped areas will then provide a low resistance access to the channel area of the transistor. This will be particularly useful in light-emitting semiconductor devices where doping with a charge transfer material shall allow contacting without using a conductor which might absorb light or reduce the performance of an organic light-emitting diode. FIG. 6 shows specifically and schematically a field-effect transistor in a thin-film technology, where a thin layer 3 of charge transfer material is provided in the channel area between the source and drain contacts and bonded to the isolating material 4 which forms the gate isolator. Simultaneously, the charge transfer material 3 also contacts the active semiconductor 6 in the channel area. The result of forming such an immobilized local doping layer of a charge transfer complex is that the lithographically defined channel length L_{def} now is reduced to an effective channel length L_{eff} as shown.

FIG. 7 shows an embodiment of the means according to the invention wherein layers 3 of charge transfer material are provided on the isolating material 4 outside the contact areas and form a charge transfer complex with the thereabove provided semiconducting layer 6. This may contribute to a better isolation of the semiconductor device and prevent undesired leakage currents. If the isolating material 4 e.g. is formed of silicon dioxide, silane can be used as bonding agent between the charge transfer material and the silicon dioxide.

According to the invention the inorganic charge transfer material may be used with a connection layer where the bonding agent is inorganic. An example is a charge transfer material in the form of arsenic or phosphor which respectively is bonded with an arsenide or phosphide layer to the underlying contact material. This may also be done directly, for instance by the contact material being a metal, e.g. copper which forms an arsenide or phosphide with respectively a charge transfer material in the form of arsenic or phosphor. Arsenic or phosphor between the contact material and the semiconductor will be bonded to the former, but yet be able to form a charge transfer complex which provides charge carriers for the semiconductor employed.

The charge transfer material may be atomic or molecular, and even if the charge transfer material together with the bond in most cases will appear as a molecular material, it is yet possible to apply atomic materials which may both provide charge transfer and useable bonds. The use of e.g. arsenic or phosphor as mentioned above are examples of atomic materials in elemental form which can be bound both to a substrate and be used as a charge transfer material.

Even though the above-mentioned examples are directed to thin-film devices with organic semiconductors, the present invention can also be used with inorganic semiconductors. A number of charge transfer molecules and functional groups are stable at temperatures which are used in the fabrication of inorganic semiconductor devices, and the means and the method according to the invention may hence be used in such devices, including devices based on amorphous silicon. Particularly the charge transfer material can be an inorganic material, for instance one of the above-mentioned.

In the means according to the invention a strong bond will be desirable. Usually the bond will be chemical, but a number of chemical bonds may have ionic or electrostatic component and in some cases will perhaps the electrostatic bond be dominating, e.g. if a polyelectrolyte material is used. As mentioned above, the organic semiconductors need not exclusively act as donors or acceptors, but can be respectively one or the other, depending on the characteristics of the charge transfer material. For instance has an organic semiconductor such as pentacene both electrons and holes as free carriers, even though up to now only hole-based devices have shown usable electrical characteristics. It might hence be used charge transfer materials which can be both acceptors or donors in a charge transfer complex with pentacene. It is also known that a charge transfer material which can be an acceptor together with one kind of organic semiconductor can be a donor together with another.

Further it is to be understood that the concept self-assembling as used in connection with mono- or multilayers of a charge transfer material does not imply that the charge transfer material forms a well-ordered layer, but that the material is assembling on a contact area or another desired area. Generally the means according to the invention does not require a regular two-dimensional structure in the self-assembling layer, even though some charge transfer materials will provide this. It may also be mentioned that it will be possible to bond a charge transfer material selectively to a specific material type, for instance a contact material or a dielectric material. This may for instance be achieved by using charge transfer compounds with material-selective functional groups. Combined with patterning by means of conventional lithographic methods, there can thus be provided selective local or patterned doping with a charge transfer material which in such a case only will be attached in exposed areas in the substrate used. The method according to the invention may in other words be used in combination with conventional lithography, even though the self-assembling property of the charge transfer material makes patterning with the use of lithography unnecessary in most cases.

The formation of a charge transfer complex in the means according to the invention reduces contact resistance or increases the injection efficiency and can increase the external field-effect carrier mobility and improve other characteristics in organic thin-film transistors. The means according to the invention may also improve the efficiency of organic light-emitting diodes or reduce their turn-off voltage.

In order to investigate the effect of using an immobilized local doping with the use of charge transfer materials, organic thin-film transistors were made where the charge transfer material acted as acceptor material. It was also made such transistors respectively without use of charge transfer material and where the charge transfer material acted as a donor material. It was expected that the charge transfer material with the acceptor properties would improve the performance of the thin-film transistor and the charge transfer material with donor properties reduce the performance thereof. This was confirmed experimentally. Transistors where the contacts were treated with an acceptor material had the best transistor performance, transistors where the contacts were treated with a donor material had the poorest performance, and transistors with untreated contacts had a performance intermediate to the other two.

Pentacene-based organic thin-film transistors with gold contacts were made with an immobilized charge transfer material of the acceptor type on the contacts. The charge transfer material used was in this case MNB. As control also similar transistors were made without charge transfer material. The transistors had a channel width W of 220 μm and a channel length L of 30 μm. A gate isolator of silicon oxide with a thickness of 253 nm/TMS and 50 nm thick contacts of gold as drain/source electrode were used. As pentacene-based organic thin-film transistors with gold contacts are hole-transporting, it was expected that the use of an acceptor material would improve the contacts by providing a local hole concentration. This was confirmed experimentally. FIG. 8a shows the I_{d}-V_{ds} characteristics of thin-film transistors with pentacene, but without MNB for different values of the gate-source voltage V_{gs}, namely 0, −10, −20, −30 and −40 V. FIG. 8b shows the I_{d}-V_{ds} characteristics for thin-film transistors with pentacene, but with the use of MNB, for the same values of gate-source voltage V_{gs} as shown in FIG. 8a. From the results it could be deduced that the carrier mobility of the transistors with untreated contacts was 0.05 cm²/Vs, while it for transistors with MNB-treated contacts was 0.24 cm²/Vs, In other words, a treatment of the contact material with an acceptor material in this case resulted in higher drain currents and better current saturation.

1. An electronic or optoelectronic device for electrical contacting or for the isolation of organic or inorganic semiconductors in electronic or optoelectric devices comprising
a substrate, either in the form of
a) a contact material consisting of an organic or inorganic electrical conductor, or
b) an isolating material consisting of an organic or inorganic dielectric;
a patterned or unpatterned charge transfer material, which is on or at a surface of the substrate;
and an organic or inorganic semiconductor,
wherein the charge transfer material forms a charge transfer complex with the organic or inorganic semiconductor,
and wherein the charge transfer material
a) comprises charge transfer components in the form of donors or acceptors,
b) forms a self-assembling layer of one or more atomic and/or molecular layers,
c) has a direct or indirect bond to the surface of the substrate, and
d) forms a donor material in the charge transfer complex if the semiconductor is an acceptor or forms an acceptor material in the charge transfer complex if the semiconductor is a donor material.

2. A device according to claim 1, wherein the bond to the surface of the substrate is a chemical or electrostatic bond or a combination thereof.

3. A device according to claim 1, wherein the charge transfer material is an organic compound.

4. A device according to claim 1, wherein the organic compound comprises a functional group which forms the bond to the surface of the substrate.

5. A device according to claim 4, wherein the functional group is material selective and forms the bond to a specific substrate material.

6. A device according to claim 1, wherein the charge transfer material is provided at the surface of the substrate and the device further comprises a connection layer without charge transfer components provided between the surface of the substrate and the charge transfer material, wherein the connection layer forms a bond to the surface of the substrate and a bond to the charge transfer material.

7. A device according to claim 6, wherein the bonds of the connection layer each is a chemical or electrostatic bond or a combination thereof.

8. A device according to claim 6, wherein the connection layer is formed of an organic bonding agent.

9. A device according to claim 8, wherein the organic bonding agent is formed of DNA molecules, such that the one half strand of a DNA molecule is bonded to the surface of a substrate and the complementary second half strand of the DNA molecule is bonded to the charge transfer material.

10. A device according to claim 1, wherein the charge transfer material is an atomic or molecular inorganic compound.

11. A device according to claim 10, wherein the charge transfer inorganic compound is provided on the surface of the substrate and is formed of a material which reacts chemically with the substrate and which forms a connection layer consisting of a chemical compound of the substrate material and the inorganic compound between the substrate and the inorganic compound.

12. A device according to claim 10, wherein the charge transfer inorganic compound is provided at the surface of the substrate and the device further comprises a connection layer provided between the substrate and the inorganic compound, wherein the connection layer comprises a chemical compound of the substrate material or a material with similar chemical properties, and the charge transfer inorganic compound.

13. A method for fabricating a device of claim 1, which comprises providing a charge transfer material as a patterned or unpatterned self-assembling layer of one or more atomic or molecular layers on or at a surface of the substrate, wherein the charge transfer material includes charge transfer components in the form of donors and/or acceptors,
forming a direct or indirect bond between the charge transfer material and the surface of the substrate,
and forming a charge transfer complex of the charge transfer material together with a thereabove adjacently provided organic or inorganic semiconductor, wherein the charge transfer material forms a donor or acceptor material in the charge transfer complex depending upon respectively whether the semiconductor itself is an acceptor or donor material.

14. A method according to claim 13, which further comprises forming the bond as a chemical or electrostatic bond or a combination thereof.

15. A method according to claim 13, which further comprises selecting the charge transfer material as an organic compound.

16. A method according to claim 15, which further comprises selecting the organic compound with a functional group which forms the bond to the surface of the substrate.

17. A method according to claim 16, which further comprises selecting the functional group as a material-selective group such that the bond is formed to a specific substrate material.

18. A method according to claim 13, wherein the charge transfer material is provided at the surface of the substrate, and which further comprises providing a connection layer without charge transfer components between the surface of the substrate and the charge transfer material, and forming the connection layer with a bond to the surface of the substrate and with a bond to the charge transfer material.

19. A method according to claim 18, which further comprises forming each bond in the connection layer as a chemical or electrostatic bond or a combination thereof.

20. A method according to claim 18, which further comprises forming the connection layer of an organic bonding agent.

21. A method according to claim 20, which further comprises forming the organic bonding agent of DNA molecules, such that the one half strand of a DNA molecule is bond to the surface of the substrate and the complementary second half strand of the DNA molecule is bond to the charge transfer material.

22. A method according to claim 13, which further comprises selecting the charge transfer material as an atomic or molecular inorganic compound.

23. A method according to claim 22, wherein the charge transfer inorganic compound is provided on the surface of the substrate, and which further comprises forming the inorganic compound of a material which reacts chemically with the substrate such that between the substrate and the inorganic compound a connection layer consisting of a chemical compound of the substrate material and the inorganic compound is formed.

24. A method according to claim 22, wherein the charge transfer inorganic compound is provided at the surface of the substrate, and which further comprises providing a connection layer consisting of a compound of the substrate material or a material with similar chemical properties, and the inorganic compound, between the substrate and the inorganic compound.

25. A device for electrical contacting or for the isolation of organic or inorganic semiconductors in electronic or optoelectric devices comprising
a substrate, either in the form of
a) a contact material consisting of an organic or inorganic electrical conductor, or
b) an isolating material consisting of an organic or inorganic dielectric; and
a patterned or unpatterned charge transfer material, which is on or at a surface of the substrate and which forms a charge transfer complex with an organic or inorganic semiconductor,
wherein the charge transfer material
a) comprises charge transfer components in the form of donors or acceptors,
b) forms a self-assembling layer of one or more atomic or molecular layers,
c) has a direct or indirect bond to the surface of the substrate,
d) forms a donor material in the charge transfer complex if the semiconductor is an acceptor or forms an acceptor material in the charge transfer complex if the semiconductor is a donor material, and
e) is made from inorganic charge transfer compound or an organic charge transfer compound selected from the group consisting of 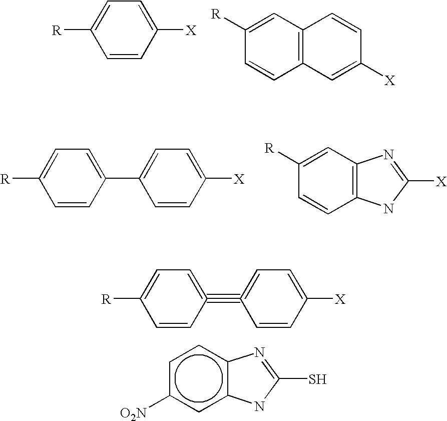
wherein R is F, Cl or NO₂ and X is —NC or SH.
